(19) United States
(12) Patent Application Publication
(10) Pub. No.: US 2012/0250335 A1
(43) Pub. Date: Oct. 4, 2012

(54) ILLUMINATION APPARATUS AND FAN UNIT FOR ILLUMINATION APPARATUS

(75) Inventor: Kenichi NAKANO, Oita (JP)

(73) Assignee: PANASONIC CORPORATION, Osaka (JP)

(21) Appl. No.: 13/412,978

(22) Filed: Mar. 6, 2012

(30) Foreign Application Priority Data
Mar. 8, 2011 (JP) 2011-050682
Mar. 23, 2011 (JP) 2011-063813

(51) Int. Cl. F21V 29/02; H01L 23/467

(52) U.S. Cl. 362/382; 165/121

(57) ABSTRACT

An illumination apparatus including an LED, a heat sink that dissipates heat of the LED, a fan apparatus provided with a blade and a motor, and a case provided with an opening on the heat sink side, wherein the fan apparatus is provided between the case and the heat sink so that the blade is arranged closer to the heat sink side than the motor. The above configuration allows the fan to be arranged in a large diameter portion of a sphere, and therefore when the illumination apparatus is applied to a bulb type LED lamp whose illumination side on which the LED is arranged is thick and whose socket side is thin, the cooling fan need not be reduced in size. Therefore, it is possible to realize an illumination apparatus having high cooling efficiency and a long useful life.

### CROSS REFERENCE TO RELATED APPLICATIONS

The disclosure of Japanese Patent Applications No. 2011 050682 filed on Mar. 8, 2011 and No. 2011-063813 filed on Mar. 23, 2011 including the specification, drawings and abstract is incorporated herein by reference in its entirety.

### TECHNICAL FIELD

The present invention particularly relates to an illumination apparatus provided with an LED and a fan unit for an illumination apparatus.

### BACKGROUND ART

In recent years, various LED (Light Emitting Diode) bulbs are being developed as illumination apparatuses as an alternative to incandescent electric lamps. These LED bulbs use a plurality of LEDs and therefore produce a large amount of heat generation. For this reason, there is a strong demand for efficiently dissipating heat generated by LEDs.

Patent Literature 1 (JP2007-265892A) describes an LED bulb that forcibly dissipates heat using a cooling fan attached inside the LED bulb and thereby improves heat dissipation efficiency.

However, when the cooling fan is mounted inside, the LED bulb described in Patent Literature 1 (JP2007-265892A) needs spaces for accommodating a lighting circuit, a fan motor and a drive circuit for this motor, and therefore such a LED bulb is not adequate for downsizing.

Patent Literature 2 (JP2010-108774A) describes a bulb type lamp using an LED as a luminous body and capable of reducing its size while securing cooling efficiency. The bulb type lamp described in JP2010-108774A is provided with a substrate including a light-emitting device on one principal surface thereof, a radiator, one end side of which is kept in absolute contact with the other principal surface of the substrate, provided with a storage section therein, an air-cooling section accommodated in the storage section of the radiator, a globe that covers the substrate and is attached on one end side of the radiator, a base provided on the other end side of the radiator, a lighting circuit accommodated between the radiator and the base for turning on a light-emitting device and a drive circuit provided on the substrate to drive the air-cooling section.

### SUMMARY OF INVENTION

### Technical Problem

However, the bulb type lamp described in Patent Literature 2 (JP2010-108774A) has a shape whose illumination side on which the LED is arranged is thick and whose socket side is thin, and therefore the size of the fan blade arranged on the socket side is regulated by the shape of the above bulb type lamp. For this reason, the size of the fan blade cannot help but be reduced, resulting in a problem that the air-blowing efficiency of the fan deteriorates.

Furthermore, in the bulb type lamp described in Patent Literature 2 (JP2010-108774A), the above substrate is located in proximity to the motor that rotates the above fan. This causes heat of the LED on the above substrate to be directly transmitted to the shaft of the above motor, resulting in a problem that the useful life of the fan attached to the shaft is shortened.

Furthermore, with the bulb type lamp described in Patent Literature 2 (JP2010-108774A), although air is sent to the radiator using the air-cooling section, the air is not concentrated on the radiator, resulting in a problem that the heat dissipation effect is hardly improved. That is, the illumination apparatus provided with the base at one end thereof has such a general shape that the thickness thereof gradually increases from the base side toward the LED side. That is, the air of the air-cooling apparatus spreads outward from the air-cooling apparatus side toward the LED side, and it is hard to manage to concentrate the air on the radiator. Therefore, the force of heat dissipation of the air generated by the air-cooling apparatus toward the radiator can be said to be weak.

### Solution to Problem

An illumination apparatus according to the present invention includes the following. An LED, a heat sink that dissipates heat of the LED, a fan apparatus including a blade and a motor, and a case provided with an opening on the heat sink side. The fan apparatus is provided between the case and the heat sink so that the blade is arranged closer to the heat sink side than the motor.

### Advantageous Effects of Invention

The present invention can arrange the fan in a large diameter portion of the bulb and thereby eliminates the need for reducing the size of the cooling fan when applied to a bulb type LED lamp whose illumination side on which the LED is arranged is thick and whose socket side is thin. Thus, it is possible to realize an illumination apparatus offering high cooling efficiency and a long useful life. Furthermore, since the motor does not contact the fan, heat of the LED does not directly transmit to the shaft of the fan, and it is therefore an object of the present invention to extend the useful life of the fan apparatus.

Furthermore, a fan unit for an illumination apparatus according to the present invention includes the following. A heat sink that dissipates heat of an LED; and a fan apparatus that includes a blade and a motor; wherein the fan apparatus is provided such that the blade is arranged closer to the heat sink side than the motor.

According to the present invention, the motor does not contact the fan and heat of the LED is never directly transmitted to the shaft of the fan, and it is therefore an object of the present invention to extend the useful life of the fan apparatus and the fan unit for an illumination apparatus. Furthermore, when mounted on the illumination apparatus, the fan unit allows the fan to be arranged in the large diameter portion of the bulb and when the fan unit is applied to a bulb type LED lamp whose illumination side on which the LED is arranged is thick and whose socket side is thin, it is not necessary to reduce the size of the cooling fan. Therefore, it is possible to provide a fan unit for an illumination apparatus capable of realizing an illumination apparatus with high cooling efficiency and a long useful life.

The present invention can provide an illumination apparatus, which may be an illumination apparatus having a shape which makes it hard to concentrate air generated by its fan apparatus on a heat sink, yet which can efficiently blow the air generated by the fan apparatus over the heat sink and improve the heat dissipation effect of the fan apparatus.

It is an object of the present invention to provide an illumination apparatus offering high cooling efficiency and long useful life, capable of avoiding the size of a cooling fan from being reduced and avoiding heat from being transmitted directly to the motor shaft of the cooling fan. Furthermore, it is another object of the present invention to provide an illumination apparatus, which may be an illumination apparatus having a shape which makes it hard to concentrate air generated by its fan apparatus on a heat sink, yet which can efficiently blow the air generated by the fan apparatus over the heat sink and improve the heat dissipation effect of the fan apparatus.

According to an aspect of the invention, an illumination apparatus of the present invention includes the following. An LED, a heat sink that dissipates heat of the LED, a fan apparatus including a blade and a motor, and a case provided with an opening on the heat sink side. The fan apparatus is provided between the case and the heat sink so that the blade is arranged closer to the heat sink side than the motor.

The present invention can arrange the fan in a large diameter portion of the bulb and thereby eliminates the need for reducing the size of the cooling fan when applied to a bulb type LED lamp whose illumination side on which the LED is arranged is thick and whose socket side is thin. Thus, it is possible to realize an illumination apparatus offering high cooling efficiency and a long useful life. Furthermore, since the motor does not contact the fan, heat of the LED is never directly transmitted to the shaft of the fan, and it is thereby possible to extend the useful life of the fan apparatus.

According to another aspect of the invention, a fan unit for an illumination apparatus according to the present invention includes the following. A heat sink that dissipates heat of an LED; a fan apparatus that includes a blade and a motor, wherein the fan apparatus is provided so that the blade is arranged closer to the heat sink side than the motor.

It is an object of the present invention to extend the useful life of a fan apparatus and a fan unit for an illumination apparatus by avoiding the motor from contacting the fan and avoiding heat of the LED from being transmitted directly to the shaft of the fan. Furthermore, when mounted on the illumination apparatus, the fan unit allows the fan to be arranged in the large diameter portion of the bulb and when the fan unit is applied to a bulb type LED lamp whose illumination side on which the LED is arranged is thick and whose socket side is thin, it is not necessary to reduce the size of the cooling fan. Therefore, it is possible to provide a fan unit for an illumination apparatus capable of realizing an illumination apparatus with high cooling efficiency and a long useful life.

The present invention can provide an illumination apparatus, which may be an illumination apparatus having a shape which makes it hard to concentrate air generated by its fan apparatus on a heat sink, yet which can efficiently blow the air generated by the fan apparatus over the heat sink and improve the heat dissipation effect of the fan apparatus.

### BRIEF DESCRIPTION OF DRAWINGS

FIG. 1 is an outside view of an illumination apparatus according to Embodiment 1 of the present invention;

FIG. 2 is an exploded perspective view of the illumination apparatus according to above Embodiment 1;

FIG. 3 is a cross-sectional view of a fan apparatus of the illumination apparatus according to above Embodiment 1;

FIG. 4 is a front view of the fan apparatus of the illumination apparatus according to above Embodiment 1;

FIG. 5 is a perspective view of the fan apparatus of the illumination apparatus according to above Embodiment 1;

FIG. 6 is a diagram illustrating a wind flow of the illumination apparatus according to above Embodiment 1;

FIG. 7 is a cross-sectional view of a fan apparatus of an illumination apparatus according to Embodiment 2 of the present invention;

FIG. 8 is a front view and a perspective view of the fan apparatus of the illumination apparatus according to above Embodiment 2;

FIG. 9 is a diagram illustrating a wind flow of the illumination apparatus according to above Embodiment 2; and

FIG. 10 is a diagram illustrating a heat dissipation effect of the fan apparatus of the illumination apparatus according to above Embodiment 2.

### DESCRIPTION OF EMBODIMENTS

Hereinafter, embodiments of the present invention will be described in detail with reference to the accompanying drawings.

### Embodiment 1

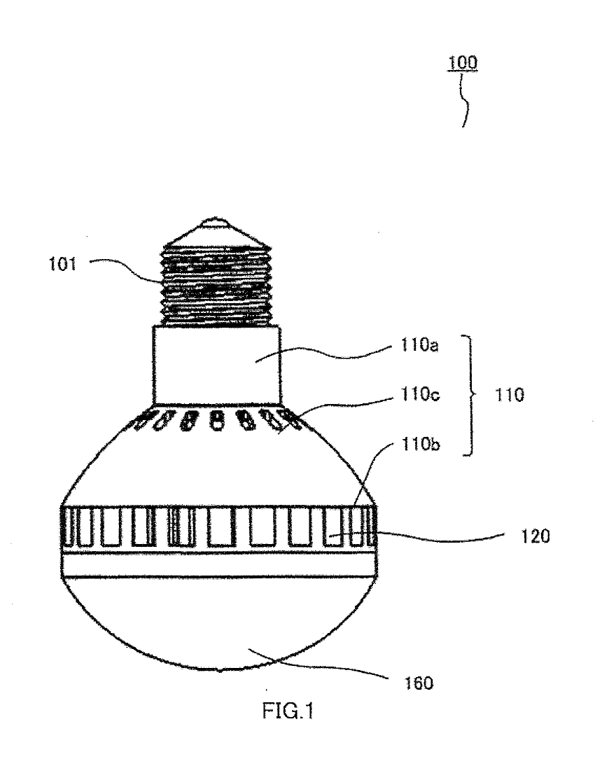

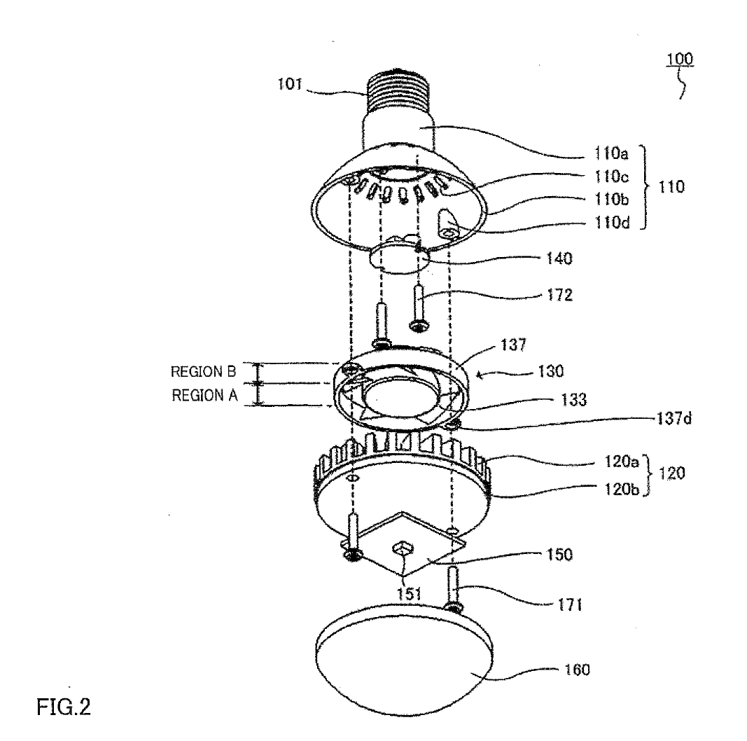

FIG. 1 is an outside view of an illumination apparatus according to Embodiment 1 of the present invention. FIG. 2 is an exploded perspective view of the above illumination apparatus. Hereinafter, the illumination apparatus according to the present invention will be described using an example embodied in a bulb type LED lamp.

As shown in FIG. 1, bulb type LED lamp 100 is configured by attaching heat sink 120 on which an LED is mounted to case 110 and attaching lens 160 to heat sink 120 so as to cover the LED.

To be more specific, as shown in FIG. 1 and FIG. 2, bulb type LED lamp 100 is provided with case 110 including base 110a at one end thereof attached to base 101 and opening 110b at the other end thereof which is open in a cylindrical shape, heat sink 120 including circumferential fin 120a attached to opening 110b in the same diameter for cooling LED 151 via LED mounting substrate 150, fan apparatus 130 supported in case 110 to blow air toward heat sink 120 and power supply substrate 140 thereof, and spherical lens 160 attached to circumferential edge 120b of heat sink 120.

Case 110 is made of a material having good heat dissipation characteristics, such as an aluminum alloy. Case 110 is formed in a hemispheric shape with its diameter gradually increasing from base 110a on one end side toward opening 110b on the other end side. Base 101 is buried in base 110a from outside. Heat sink 120 having circumferential fin 120a is fixed to opening 110b at the other end of case 110 of substantially the same diameter by screw 171 screwed into threaded hole 110d on the inner wall of case 110 together with flange through hole 137d of fan apparatus 130 set up in case 110. Furthermore, on the outer circumferential surface of case 110, a plurality of intake ports 110c are formed into an elongated hole shape along the axial direction of case 110, spaced separated from each other in the circumferential direction.

Base 101 is, for example, of an E17 type, electrically connected to power supply substrate 140 and the LED mounting substrate 150 side via a wire (not shown) and is threaded so that base 101 is screwed into a lamp socket of bulb type LED lamp 100.

Fan apparatus 130 is screwed to one end side of case 110 in case 110 separated from the inner wall of case 110 together with heat sink 120.

Fan apparatus 130 cools heat sink 120 by generating an air flow via heat sink 120. Fan apparatus 130 may be a centrifugal fan, axial flow fan or any other fan.

Fan apparatus 130 is mounted with power supply substrate 140 on the base 110a side, and power supply substrate 140 is attached to the inner wall of base 110a by screw 172.

Furthermore, fan apparatus 130 includes motor 131 accommodated in frame 137. Frame 137 in which motor 131 is accommodated is screwed into threaded hole 110d on the inner wall of case 110 from the bottom through flange through hole 137d by screw 171 together with heat sink 120.

Thus, unlike the conventional configuration in which a motor is mounted on an LED mounting substrate or a power supply substrate, fan apparatus 130 is attached in case 110 so that the non-mounting portion of blade 133 basically faces the base 110a side in case 110. According to the present embodiment, frame 137 in which motor 131 is accommodated is screwed into threaded hole 110d on the inner wall of case 110 by screw 171 together with heat sink 120. That is, fan apparatus 130 is not fixed to the LED mounting substrate or the power supply substrate but attached to base 110a in case 110. As a result, power supply substrate 140 is directly attached to base 110a in case 110 separated from LED mounting substrate 150.

Since LED mounting substrate 150 and power supply substrate 140 are arranged to be separated from each other, mutual heat generation is distributed and this provides an advantage of improving the cooling effect.

LED mounting substrate 150 mounted with LED 151 is attached to heat sink 120, which cools heated LED 151 mounted on LED mounting substrate 150. Heat sink 120 is provided with circumferential fin 120a, which improves the cooling effect.

Heat sink 120 is made of a metal material having good thermal conductivity such as aluminum, and lets the air from fan apparatus 130 accommodated in the central part escape out of circumferential fin 120a which is an exhaust port formed around the outer circumference.

Spherical, lens 160 is attached to circumferential edge 120b of heat sink 120.

Heat sink 120 is arranged so as to be sandwiched between case 110 and lens 160.

Intake port 110c of case 110 and circumferential fin 120a which is the exhaust port of heat sink 120 may have mutually opposite wind directions.

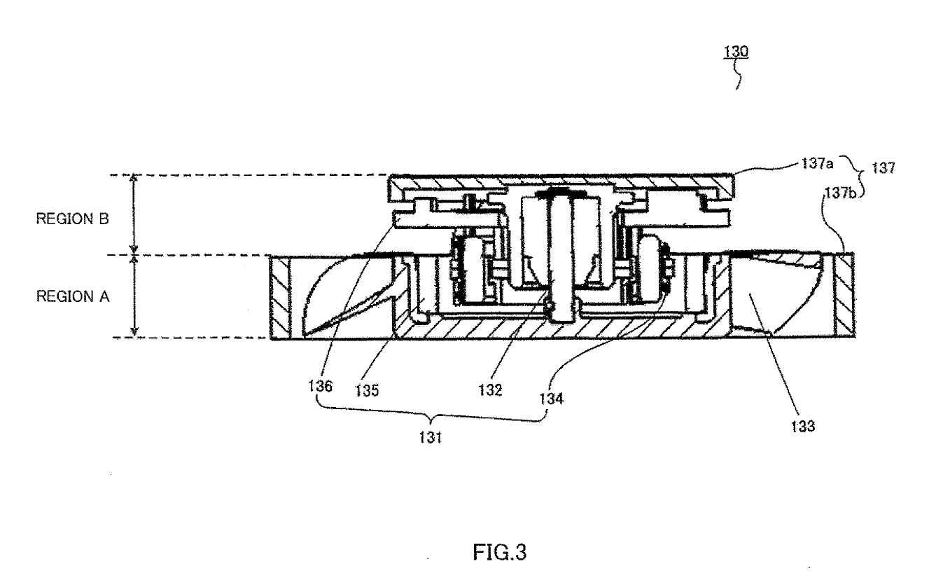

Fan apparatus 130 has motor 131 (FIG. 3) with blade 133 attached to a shaft end thereof, and arranges blade 133 on the heat sink 120 side. Details of fan apparatus 130 will be described later.

Power supply substrate 140 is a power supply circuit to supply DC power to fan apparatus 130.

LED mounting substrate 150 mounts LED 151. LED mounting substrate 150 is a metal base substrate made of a metal material having good heat dissipation characteristics such as aluminum or an insulating material. LED mounting substrate 150 is heat-dissipated in contact with heat sink 120.

LED mounting substrate 150 is provided in contact with heat sink 120 that cools heated LED 151.

Lens 160 is made of glass or synthetic resin having light diffusing ability, formed into a flat spherical shape and covers LED mounting substrate 150 to spread light from LED 151.

Thus, power supply substrate 140, fan apparatus 130, heat sink 120 and LED mounting substrate 150 are arranged in order from the base 110a side of case 110 in the interior space between case 110 and lens 160.

Lens 160 is bonded to heat sink 120 and LED mounting substrate 150 and LED 151 are arranged between lens 160 and heat sink 120.

Power supply substrate 140 mounts a power supply section that supplies power to fan apparatus 130.

Power supply substrate 140 is fixed to case 110 by screw 172 (FIG. 2), and heat sink 120 and fan apparatus 130 are fixed to case 110 by screw 171 (FIG. 2).

Fan apparatus 130 and heat sink 120 have a circular shape and heat sink 120 has a greater diameter than fan apparatus 130. Furthermore, fan apparatus 130 and heat sink 120 may be integrated into one unit.

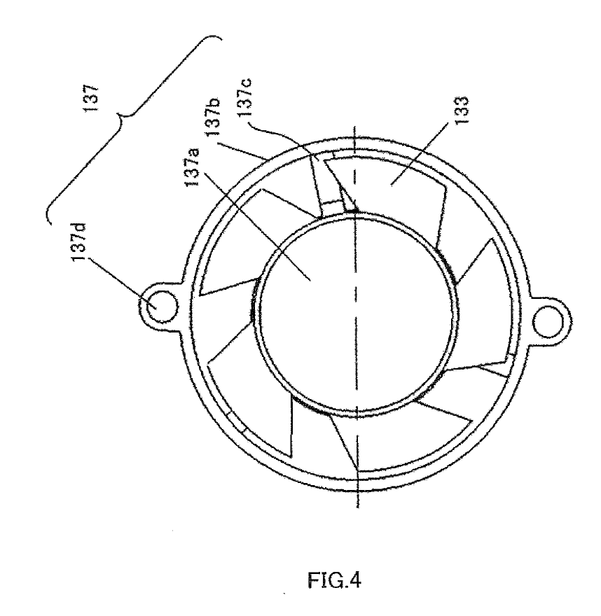

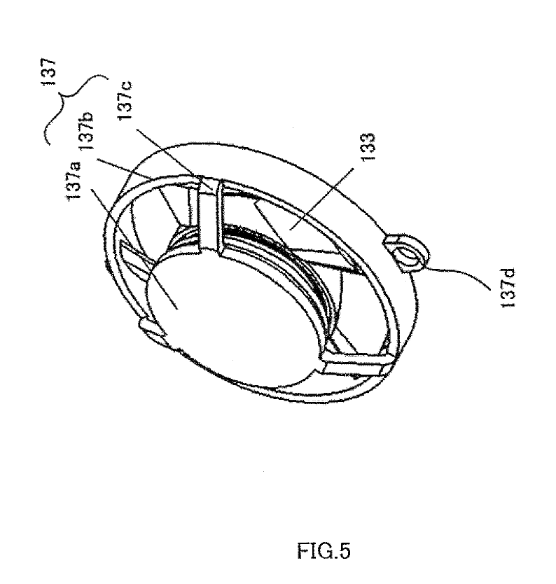

FIG. 3 is a cross-sectional view of the fan apparatus of the illumination apparatus according to the present embodiment, FIG. 4 is a front view of the above fan apparatus and FIG. 5 is a perspective view of the above fan apparatus.

As shown in FIG. 3 to FIG. 5, fan apparatus 130 is configured by integrating into one unit, motor 131, shaft 132, blade 133 driven to rotate by shaft 132, stator 134, ring-shaped magnet 135, fan apparatus control substrate 136 and frame 137 that covers the outer circumference of blade 133. Blade 133 is attached to an edge of shaft 132 of motor 131.

That is, in fan apparatus 130, the edge of shaft 132 to which blade 133 is attached is arranged on the heat sink 120 side, and the portion of shaft 132 to which blade 133 is not attached is arranged on one end side of case 110. Furthermore, fan apparatus 130 is provided with frame 137 that covers the outer circumference of blade 133, and frame 137 contacts heat sink 120, but frame 137 does not contact blade 133 or shaft 132.

Above shaft 132, stator 134, ring-shaped magnet 135 and fan apparatus control substrate 136 configures constitute motor 131 as a whole.

Frame 137 is provided with flange through hole 137d for screw 171 (FIG. 2) and screw 171 passes through flange through hole 137d and fixes fan apparatus 130 to case 110.

Here, frame 137 contacts heat sink 120, whereas it does not contact other parts such as blade 133, shaft 132 and stator 134. For this reason, heat of heat sink 120 does not directly transfer to other parts such as blade 133, shaft 132 and stator 134. Furthermore, frame 137 and heat sink 120 may also be configured to be spaced from each other so as not to have direct contact with each other.

Frame 137 is provided with flat portion 137a that supports blade 133, shaft 132, stator 134 or the like and peripheral portion 137b formed so as to surround blade 133. Flat portion 137a and peripheral portion 137b are connected together via a plurality of leg portions 137c.

Shaft 132 is rotatably supported by flat portion 137a, and rotates blade 133. Blade 133 is driven to rotate by ring-shaped magnet 135 and stator 134.

Stator 134 is formed of metal plates made of a magnetic material stacked one on another in the axial direction of the axis of rotation. An insulating layer is formed on each teeth portion of stator 134 through electrocoating or the like, and each teeth portion is wound with a coil via this insulating layer. A magnetic field is generated by passing a current through this coil, and stator 134 is driven by attraction to or repulsion by magnet 135.

The structure of the drive section is not limited to the above structure, but any structure may be used as long as it is a structure capable of driving fan apparatus 130.

Hereinafter, the arrangement direction of fan apparatus 130, which is a feature of the present invention, will be described.

Shaft 132 is made up of a blade 133 mounting portion (see region A in FIG. 3) and a blade 133 non-mounting portion (see region B in FIG. 3), and the outer diameter of the blade 133 mounting portion is by far greater than the outer diameter of the non-mounting portion. Furthermore, since there is frame 137 that arranges the wind direction around the outer circumference of the blade 133 mounting portion, the outer diameter of the blade 133 mounting portion is quite large as shown in FIG. 3. Furthermore, wind power of the blade 133 mounting portion is also strong.

In the present embodiment, fan apparatus 130 is set up in case 110 so that the blade 133 mounting portion having a larger outer diameter and stronger wind force faces LED mounting substrate 150 via heat sink 120. When fan apparatus 130 is arranged in this way, the blade 133 non-mounting portion (see FIG. 3B) is set up so as to face base 110a in case 110. Now, observing the shape of case 110 again, case 110 has a hemispheric shape with the diameter thereof decreasing toward base 110a and opening 110b gradually increasing. Therefore, the non-mounting portion (see FIG. 3B) of blade 133 is well fitted into base 110a side in case 110, while the blade 133 mounting portion is accommodated inside opening 110b of case 110 together with frame 137 with a sufficient space. In other words, it is possible to use a blade of a large diameter according to the size of opening 110b of case 110 and realize a noiseless fan apparatus with high cooling efficiency.

Hereinafter, operation of the illumination apparatus configured as shown above will be described.

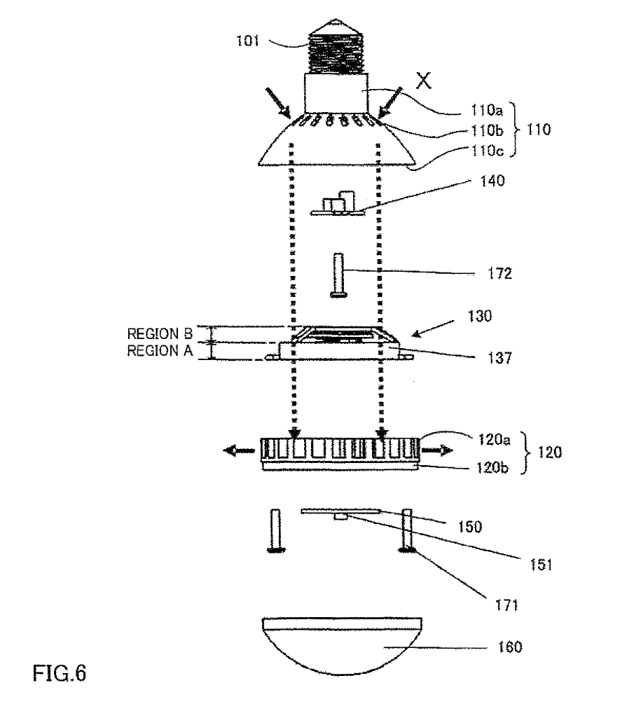

FIG. 6 is a diagram illustrating a wind flow of the apparatus according to the embodiment of the present invention. In FIG. 6, arrows of solid and broken lines indicate wind flows.

As shown in FIG. 6, stator 134 of fan apparatus 130 is arranged on the base 110a side and blade 133 is arranged on the heat sink 120 side. Furthermore, frame 137 is in contact with heat sink 120, whereas it is not in contact with blade 133 or shaft 132.

Adopting such a configuration prevents heat from directly transferring from heat sink 120 toward shaft 132, therefore making it possible to extend the useful life of the fan and the fan apparatus. Furthermore, blade 133 can be formed in a large size. That is, the outer diameter of case 110 is small on the base 110a side and large on the lens 160 side. This is because the thickness of base 101 of base 110a is specified. On the other hand, the diameter of lens 160 is large so as to provide light of LED 151 over a wide range.

In the present embodiment, fan apparatus 130 arranges the edge of shaft 132 to which blade 133 is attached on the heat sink 120 side, and arranges the portion of shaft 132 to which blade 133 is not attached on one end side of case 110. That is, blade 133 can be formed in a large size by arranging stator 134 of motor 131 on the base 110a side and arranging blade 133 on the heat sink 120 side.

Furthermore, to improve the air-blowing efficiency of fan apparatus 130, peripheral portion 137b of frame 137 is required around blade 133 to regulate the wind direction. The air-blowing efficiency will deteriorate if there is no peripheral portion 137b. Region A in FIG. 3 is a region in which peripheral portion 137b is provided and is a region where the size of fan apparatus 130 is large in the diameter direction of fan apparatus 130. On the other hand, in region B where blade 133 does not exist, only flat portion 137a, fan apparatus control substrate 136 and part of stator 134 or the like exist. Since there is no need to form peripheral portion 137b, this is a region where the size of fan apparatus 130 can be configured to be smaller in the diameter direction of fan apparatus 130.

Thus, by arranging region A on the heat sink 120 side and region B on the base 110a side, it is possible to form blade 133 in a large size even when the size of case 110 is the same. As a result, the air-blowing efficiency of fan apparatus 130 improves and since the size of blade 133 is large, it is possible to realize a noise reduction.

As described so far, bulb type LED lamp 100 according to the present embodiment is provided with case 110 including base 110a at one end thereof attached to base 101, and opening 110b at the other end thereof which is open in a cylindrical shape, heat sink 120 including circumferential fin 120a attached to opening 110b in the same diameter and cooling LED mounting substrate 150, fan apparatus 130 supported in case 110 to blow air toward heat sink 120 and power supply substrate 140 thereof, and spherical lens 160 attached to circumferential edge 120b of heat sink 120.

Fan apparatus 130 includes motor 131 and blade 133 that rotates by being attached to one end in the axial direction of shaft 132 of motor 131, and the distal end of shaft 132 to which blade 133 is attached is arranged on the heat sink 120 side and the portion of shaft 132 to which blade 133 is not attached is arranged on one end side of case 110. Furthermore, fan apparatus 130 is provided with frame 137 that covers the outer circumference of blade 133, and frame 137 is in contact with heat sink 120, whereas frame 137 is not in contact with blade 133 or shaft 132.

According to this configuration, when applied to a bulb type lamp whose illumination side on which the LED is arranged is thick and whose socket side is thin, the fan can be arranged in the large diameter portion of the bulb, and it is thereby possible to realize an illumination apparatus with high cooling efficiency and a long useful life without reducing the size of the blade of the fan. Furthermore, heat of LED 151 is never directly transmitted to the shaft of the motor of the cooling fan, which makes it possible to extend the useful life of the fan and the fan apparatus.

Furthermore, since LED mounting substrate 150 and power supply substrate 140 are arranged to be separated from each other, mutual heat generation is distributed and there is an advantage of improving the cooling effect.

### Embodiment 2

Embodiment 2 will describe frame 137 irrespective of the vertical arrangement of fan apparatus 130. Components assigned the same reference numerals as those in Embodiment 1 will be described as identical ones.

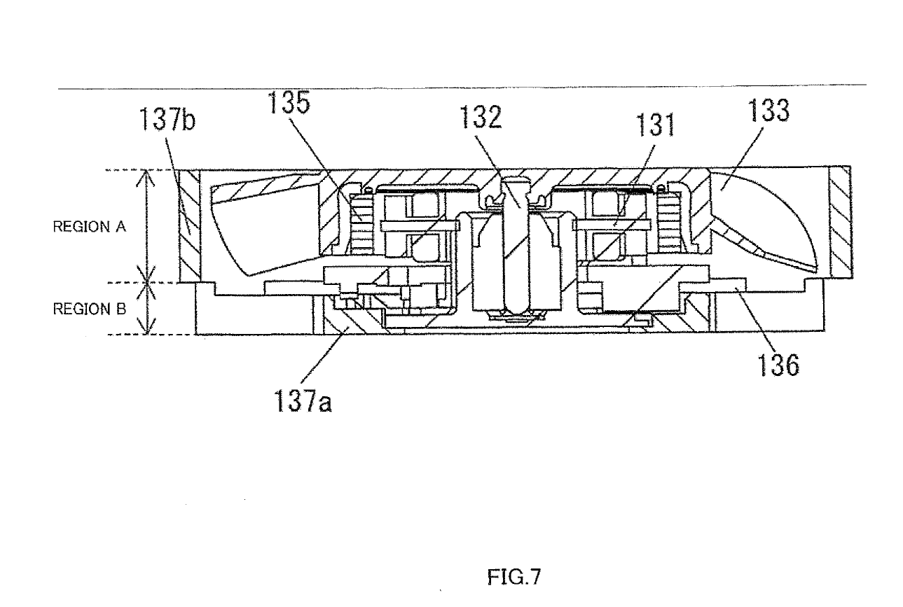

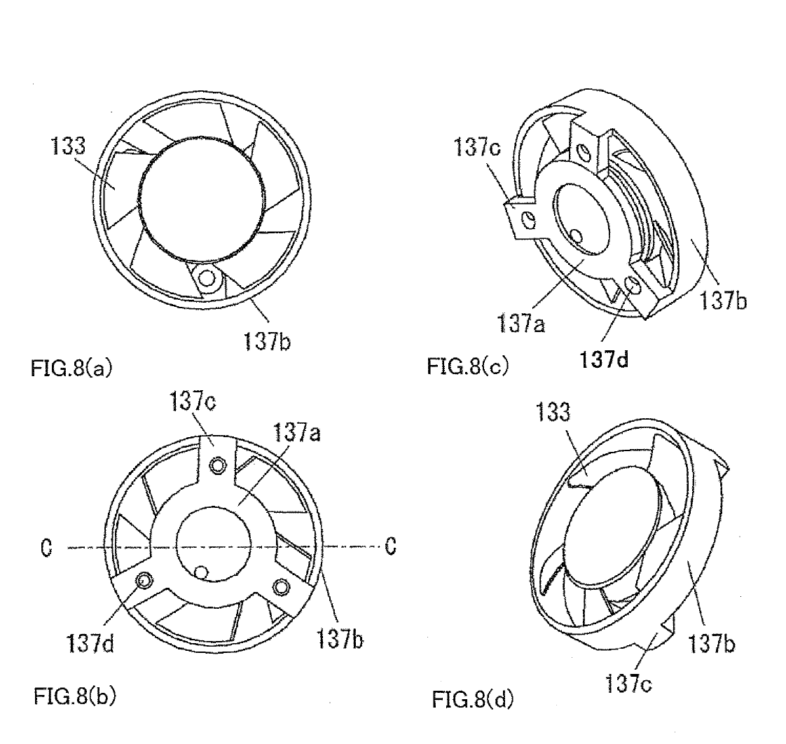

FIG. 7 is a cross-sectional view of a fan apparatus of an illumination apparatus according to Embodiment 2 of the present invention. FIG. 8 is a front view and a perspective view of the fan apparatus of the illumination apparatus according to the above embodiment.

As shown in FIG. 7, fan apparatus 130 includes motor 131 and blade 133 that rotates by being attached to one end in the axial direction of shaft 132 of motor 131. In FIG. 7, the distal end of shaft 132 to which blade 133 is attached is arranged on one end side of case 110, and the portion of shaft 132 to which blade 133 is not attached is arranged on the heat sink 120 side. Furthermore, the distal end of shaft 132 to which blade 133 is attached may be arranged on the heat sink 120 side and the portion of shaft 132 to which blade 133 is not attached may be arranged on one end side of case 110. Furthermore, fan apparatus 130 is provided with frame 137 that covers the outer circumference of blade 133, frame 137 is in contact with heat sink 120, whereas it is not in contact with blade 133 or shaft 132.

Heat sink 120 is screwed to one end side of case 110 in case 110 to be separated from the inner wall of case 110. Fan apparatus 130 is screwed to heat sink 120. Of course, another mode may also be adopted in which fan apparatus 130 is screwed to one end side of case 110 in case 110 to be separated from the inner wall of case 110 together with heat sink 120. Furthermore, fan apparatus 130 may also be accommodated so as to be covered with heat sink 120 and fin 120a on the bottom surface and in the centrifugal direction.

Fan apparatus 130 cools heat sink 120 by generating an air flow via heat sink 120.

Fan apparatus 130 is configured by integrating into one unit, motor 131, blade 133 driven to rotate by motor 131 and frame 137 that covers the outer circumference of blade 133. Blade 133 is attached to shaft 132 of the motor. Shaft 132 may be attached so as to extend from the base 101 side or may be attached so as to extend from the heat sink 120 side.

Furthermore, the configuration in which shaft 132 is attached so as to extend from the heat sink 120 side exerts the following effect. That is, since frame 137 can be firmly fixed to the heat sink, so that the strength improves. Blade 133 rotates around shaft 132, and heat sink 120 can rotatably support blade 133. Furthermore, since heat sink 120 firmly fixes motor 131 and blade 133, thereby suppress vibration due to the rotation of blade 133 or the like and suppress noise.

Fan apparatus 130 is mounted with power supply substrate 140 on the base 110a side, and power supply substrate 140 is attached to the inner wall of base 110a by screw 172. Electronic parts such as a capacitor are mounted on power supply substrate 140, and these electronic parts are arranged at the farthest possible distance from LED 151, closer to the base 101 side than fan apparatus 130 so that heat is not transmitted to the electronic parts.

Furthermore, fan apparatus 130 is configured such that motor 131 and blade 133 or the like are accommodated in frame 137. Fan apparatus 130 is screwed to heat sink 120 by a screw. Furthermore, frame 137 in which motor 131 is accommodated may be screwed into threaded hole 110d on the inner wall of case 110 by screw 171 through flange through hole 137d from the bottom together with heat sink 120.

Since the LED mounting substrate and the power supply substrate are arranged to be separated from each other, mutual heat generation is distributed and there is an advantage of improving the cooling effect.

LED mounting substrate 150 mounted with LED 151 is attached to heat sink 120, and heat sink 120 cools heated LED 151 mounted on LED mounting substrate 150. Heat sink 120 is provided with fin 120a, which improves the cooling effect. Fan apparatus 130 may be arranged so as to cover the upward part of fin 120a of heat sink 120, or fan apparatus 130 may be arranged so that fin 120a covers the periphery thereof. Arranging fan apparatus 130 so as to cover the upward part of fin 120a of heat sink 120 makes it possible to form blade 133 of fan apparatus 130 in a large size in the centrifugal direction. Blade 133 can be formed in a large size in the centrifugal direction because fin 120a does not prevent fan apparatus 130 from expanding. This improves the air-blowing efficiency of fan apparatus 130 and improves the cooling effect of fan apparatus 130.

Furthermore, arranging fan apparatus 130 so that fin 120a covers the periphery thereof allows fin 120a to efficiently heat-dissipate the air exhausted by fan apparatus 130. This allows heated LED 151 to be efficiently cooled. Particularly, fin 120a is preferably provided around region B (gap) in the centrifugal direction. Fin 120a is configured to have a height equal to or greater than the height of region B in the axial direction. This allows the wind that flows from inside of fan apparatus 130 toward the outside in region B to be blown over fin 120a sufficiently. As a result, heat transmitted to fin 120a can be efficiently dissipated. That is, the air exhausted from exhaust port 120a (in the present embodiment, fin 120a also functions as an exhaust port) after the heat dissipation by heat sink 120 can be reused for heat dissipation of fin 120a.

FIG. 8(a) is a front view of the above fan apparatus, FIG. 8(b) is a rear view of the above fan apparatus, FIG. 8(c) is a perspective view from the rear side of the above fan apparatus and FIG. 8(d) is a perspective view from the front side of the above fan apparatus.

As shown in FIG. 7 and FIG. 8, fan apparatus 130 is configured by integrating into one unit, motor 131, shaft 132, blade 133 driven to rotate by shaft 132, a stator, ring-shaped magnet 135, fan apparatus control substrate 136 and frame 137 that covers the outer circumference of blade 133. Blade 133 is attached to a distal end of shaft 132 of motor 131.

Above shaft 132, stator, ring-shaped magnet 135 and fan apparatus control substrate 136 configures constitute motor 131 as a whole.

Frame 137 is fixed to heat sink 120 by a screw that passes through flange through hole 137d, and heat sink 120 is fixed to case 110 by screw 171.

Here, frame 137 is in contact with heat sink 120, whereas it is not in direct contact with other parts such as blade 133, shaft 132, stator. Therefore, heat of heat sink 120 is not directly transferred to other parts such as blade 133, shaft 132, and stator. Furthermore, frame 137 and heat sink 120 may be configured so as not to directly contact each other by leaving a space therebetween.

Frame 137 is provided with flat portion 137a that supports blade 133, shaft 132, stator or the like and peripheral portion 137b formed so as to surround the periphery of blade 133. Flat portion 137a and peripheral portion 137b are connected together via a plurality of leg portions 137c. In the present embodiment, there are three leg portions 137c, and it is preferable that at least two leg portions 137c be provided. Though the number of leg portions is not limited to this, if two leg portions 137c are provided, they are preferably formed in a large thickness to increase the strength. In that case, the wind flow is obstructed, and therefore three or more thin leg portions 137c are preferably formed. In the present embodiment, the thickness of leg portion 137c is approximately 4 mm to 8 mm. Furthermore, in the present embodiment, the outer diameter of peripheral portion 137b is approximately 30 mm. Furthermore, flat portion 137a and peripheral portion 137b may be integrally formed with a plurality of leg portions 137c as one unit or may be formed separately and then bonded together.

Hereinafter, operation of the illumination apparatus configured as shown above will be described.

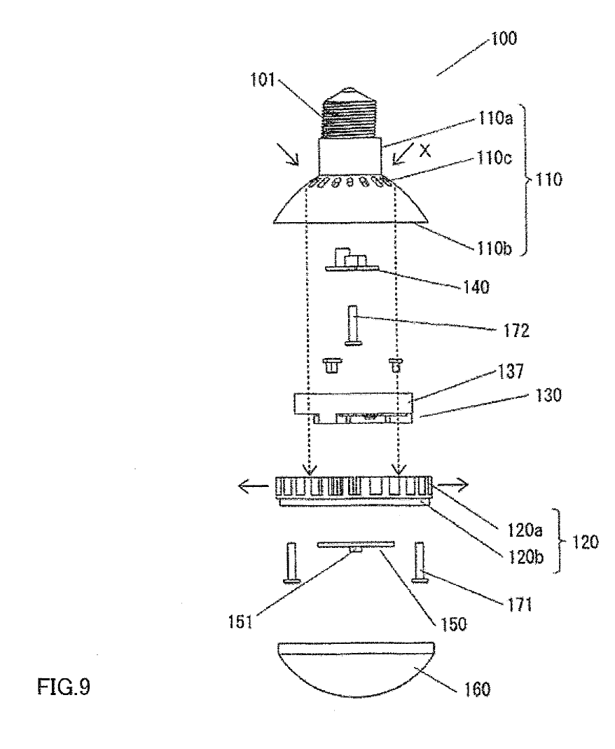

FIG. 9 is a diagram illustrating a wind flow of the illumination apparatus according to the embodiment of the present invention. In FIG. 9, arrows with solid and broken lines indicate wind flows.

As shown in FIG. 9, air is taken in from intake port 110c and exhausted from exhaust port 120a made up of a gap between fins 120a. However, the wind flow may be in a direction opposite to the aforementioned one.

Next, peripheral portion 137b will be described in detail.

As shown in FIG. 7, the periphery of motor 131 and blade 133 in the centrifugal direction is divided into region A on the blade 133 side and region 13 on the motor 131 side. Region A is a region where peripheral portion 137b is provided in the periphery of motor 131 and blade 133 in the centrifugal direction, and region B is a region without peripheral portion 137b. As shown in FIG. 8(c), leg portion 137c is also formed in region B, but at least part of peripheral portion 137b is removed. In region B, it is preferable that gaps which constitute air courses be provided in all parts except leg portion 137c of ring-shaped frame 137, but gaps need not always be provided around the entire circumference.

The ratio in width in the axial direction of the motor between region A and region B is preferably approximately 2 to 4:1. That is, region A is preferably formed to be greater than region B. This is because the air course is controlled in region A, and therefore the air course can be more effectively controlled by making region A greater than region B. The ratio, however, is not limited to this and may also be, for example, approximately 1:1 or approximately 5:1. Furthermore, in the axial direction, at least peripheral portion 137b may be configured to surround 50% or more of blade 133. That is, the width of the height of peripheral portion 137b in the axial direction may be approximately 50% to 140% of the height of blade 133 in the axial direction, and preferably 80% to 120%. The wind direction can be controlled if the height of peripheral portion 137b can be secured to such a degree.

Furthermore, when the air-blowing efficiency is taken into consideration, if the top end of peripheral portion 137b and the top end of the hub that supports blade 133 extend in a straight line as shown in the upper part of FIG. 7, the wind direction can be efficiently regulated without wasting the wind generated by rotation of blade 133. Therefore, it is possible to efficiently make the wind concentrate on heat sink 120 and improve the cooling effect. Peripheral portion 137b may start from closer to the motor side than the top end of the hub. In that case, the vicinity of the top end of the hub is not surrounded by peripheral portion 137b and is neither region A nor region B. Therefore, peripheral portion 137b need not surround entire blade 133 and blade 133 may stick out of peripheral portion 137b on one or both of base 101 side and heat sink 120 side. However, when entire blade 133 is surrounded by peripheral portion 137b, it is possible to efficiently regulate the wind direction and blow the air over heat sink 120 in a more concentrated manner. That is to say, it is possible to prevent the air course of the air taken into the illumination apparatus from crossing the air course of the air exhausted from the illumination apparatus, and at the same time form an air course that allows the air to deprive heat sink 120 of heat more easily.

Furthermore, in the present embodiment, peripheral portion 137b is formed substantially parallel to the axial direction of fan apparatus 130 and in a ring shape. Peripheral portion 137b may be inclined with respect to the axial direction of fan apparatus 130 or heat sink 120. For example, forming peripheral portion 137b into a substantially conical shape, that is, forming it to be thinner on the base 101 side and thicker on the heat sink 120 side will increase the wind velocity and improve the cooling effect of fan apparatus 130. Furthermore, the air taken in can be efficiently blown over heat sink 120, thereby reducing loss of the wind. Furthermore, making the base 101 side thicker and the heat sink 120 side thinner as a substantially conical shape can avoid superfluous air circulation. Furthermore, the air exhausted from exhaust port 120a is prevented from being directly exhausted from intake port 110c, which makes it possible to prevent a warm air from mixing with the air blown over heat sink 120. As a result, the cooling effect can be improved.

in the present embodiment, flat portion 137a of fan apparatus 130 is arranged so as to contact heat sink 120, the height of region A in the axial direction is approximately 5 mm, the height of region B is approximately 3 mm and the height of fan apparatus 130 is approximately 8 mm. In this case, region B refers to a gap between heat sink 120 and the bottom part of peripheral portion 137b. Furthermore, when flat portion 137a of fan apparatus 130 does not contact heat sink 120, the gap corresponds to the distance between fan apparatus 130 and heat sink 120 added to the height of region B. The height of fan apparatus 130 is approximately 8 mm, and when fan apparatus 130 contacts heat sink 120, region B is preferably 2 to 4 mm. When it is 2 mm or less, peripheral portion 137b obstructs the air course excessively, and when it is 4 mm or more, peripheral portion 137b cannot sufficiently regulate the air course.

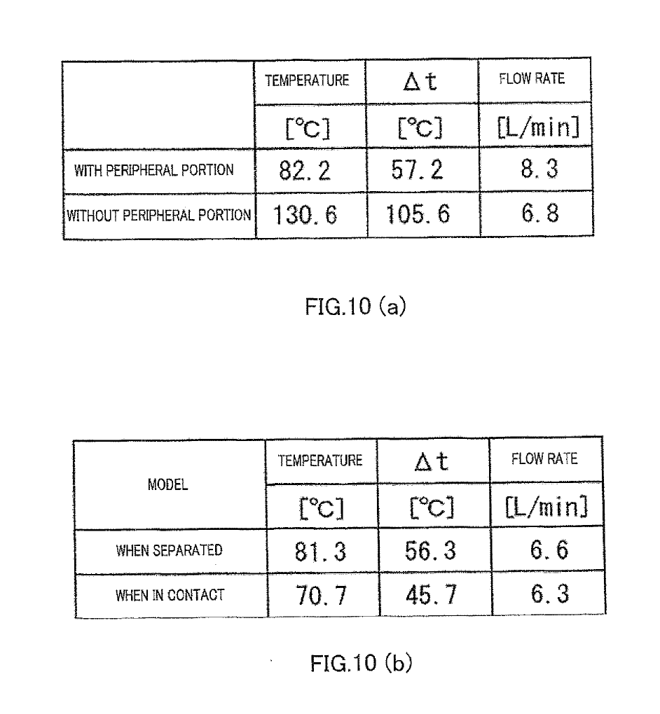

FIG. 10 is a diagram illustrating heat dissipation effects of the fan apparatus of the illumination apparatus according to the above embodiment.

FIG. 10(a) is a diagram illustrating differences in heat dissipation effects between when the peripheral portion is provided and when it is not provided. At this time, in peripheral portion 137b, the height of region A in the axial direction is approximately 5 mm, the height of region B is approximately 3 mm and the height of fan apparatus 130 is approximately 8 mm. Furthermore, FIG. 10(b) is a diagram illustrating differences in heat dissipation effects depending on the position of the blade, assuming the distance between the heat sink and the distal end portion of the peripheral portion is constant. Suppose the distance between heat sink 120 and the distal end portion of peripheral portion 137b is 3 mm. At this time, “when separated” in the upper section refers to an arrangement where heat sink 120 is located at a distance of 3 mm from the bottom of shaft 132. Furthermore, “when in contact” in the lower section refers to an arrangement where heat sink 120 is located so as to contact the bottom of shaft 132. In both cases, the number of revolutions of fan apparatus 130 is 5000 r/min, and the amount of heat generation of LED 151 is 12 W. The temperature shown in FIG. 10 is a temperature of LED mounting substrate 150 when LED 151 is turned ON. Δt represents a temperature after subtracting 25° from the above temperature, that is indicates a degree by which the measured temperature is higher than an ordinary temperature, and the flow rate represents the flow rate of the air taken in from intake port 110c and exhausted from exhaust port 120a.

It is clear from FIG. 10(a) that the heat dissipation effect is improved by nearly 50° C. by only providing peripheral portion 137b compared to when it is not provided. Furthermore, the difference from the normal temperature (25° C.) when peripheral portion 137b is not provided is approximately twice that when peripheral portion 137b is provided. Furthermore, when peripheral portion 137b is provided, the air-blowing efficiency of fan apparatus 130 is also improved and the heat dissipation effect with respect to LED mounting substrate 150 is apparently improved.

Furthermore, it is clear from FIG. 10(b) that fan apparatus 130 is preferably located as close as possible from heat sink 120. Although fan apparatus 130 need not always contact heat sink 120, the cooling effect with respect to LED mounting substrate 150 improves as the distance between the two decreases. However, separating fan apparatus 130 from heat sink 120 and inserting an air layer or heat insulating material or the like in the gap therebetween has a merit that heat of heat sink 120 is not directly transmitted to fan apparatus 130. That is it is possible to prevent the useful life of fan apparatus 130 from being shortened due to heat generation, and extend the useful life of fan apparatus 130.

Furthermore, although motor 131 is arranged on the heat sink 120 side and blade 133 is arranged on the base 101 side in the present embodiment, blade 133 may be arranged on, the heat sink 120 side and motor 131 on the base 101 side. In such a case, region A is on the motor 131 side and region B is on the blade 133 side. That is, in order to blow the air over the heat sink in a concentrated manner, region A is always on the base 101 side and region 13 is always on the heat sink side so that the air whose direction is regulated by peripheral portion 137b in region A is efficiently concentrated on heat sink 120 in region B.

Furthermore, fin 120a may be provided at least in the periphery of region B in the centrifugal direction. That is, fin 120a is configured to have a height equal to or greater than the height of region B in the axial direction so that the air flowing from inside to outside of fan apparatus 130 in region B is sufficiently blown over fin 120a.

Furthermore, fan apparatus 130 is preferably located as close as possible to heat sink 120. That is the air at a higher flow rate in the vicinity of heat sink 120 can dissipate more heat from heat sink 120, therefore, the cooling effect is improved.

The description so far is just an exemplified explanation for preferred embodiments of the present invention, and the scope of the present invention is not limited to this.

The terms “fan apparatus” and “illumination apparatus” have been used in each embodiment above, but these are only usage for convenience and the term may also be “fan apparatus or the like.”

Furthermore, each component making up each of the above fan apparatus and illumination apparatus, such as the type of the case, substrate is not limited to the above embodiments.

### INDUSTRIAL APPLICABILITY

The illumination apparatus according to the present invention is suitable for use in a bulb type LED lamp provided with a fan apparatus that cools an LED mounting substrate.

1. An illumination apparatus comprising:
an LED;
a heat sink that dissipates heat of the LED;
a fan apparatus comprising a blade and a motor; and
a case provided with an opening on the heat sink side, wherein:
the fan apparatus is provided between the case and the heat sink so that the blade is arranged closer to the heat sink side than the motor.

2. The illumination apparatus according to claim 1, wherein the fan apparatus comprises a first frame that covers an outer circumference of the blade.

3. The illumination apparatus according to claim 2, wherein the first frame is in contact with the heat sink and is located to be separated from the blade.

4. The illumination apparatus according to claim 2, wherein the first frame is in contact with the heat sink and the blade is located to be separated from the heat sink.

5. The illumination apparatus according to claim 1, wherein the fan apparatus is screwed to the case together with the heat sink.

6. The illumination apparatus according to claim 1, further comprising a second frame that supports the fan apparatus on the motor side, wherein:
the fan apparatus is arranged between the second frame, and the heat sink and the blade is located closer to the heat sink side than the motor.

7. The illumination apparatus according to claim 1, wherein the case comprises an intake port, and the heat sink comprises an exhaust port, and the fan apparatus exhausts air taken in from the intake port from the exhaust port.

8. A fan unit for an illumination apparatus, comprising:
a heat sink that dissipates heat of an LED; and
a fan apparatus comprising a blade and a motor, wherein:
the fan apparatus is provided so that the blade is located closer to the heat sink side than the motor.

9. The fan unit for an illumination apparatus according to claim 8, wherein the fan apparatus comprises a first frame that covers an outer circumference of the blade.

10. The fan unit for an illumination apparatus according to claim 9, wherein the first frame is in contact with the heat sink and is located to be separated from the blade.

11. The fan unit for an illumination apparatus according to claim 10, wherein the first frame is in contact with the heat sink and the blade is located to be separated from the heat sink.

12. The fan unit for an illumination apparatus according to claim 8, further comprising a second frame that supports the fan apparatus, wherein:
the fan apparatus is arranged between the second frame and the heat sink, and
the blade is located closer to the heat sink side than the motor.

13. The fan unit for an illumination apparatus according to claim 9, further comprising a second frame that supports the fan apparatus from the motor side, wherein:
the first frame and the second frame are connected together via a plurality of leg portions, and the plurality of leg portions are located to be separated from each other and the fan apparatus takes in air from gaps between the plurality of leg portions.
